(19) United States
(12) Patent Application Publication
(10) Pub. No.: US 2026/0196974 A1
(43) Pub. Date: Jul. 9, 2026

(54) HIGH-VOLTAGE POWER SUPPLY AND VOLTAGE MODULATOR

(71) Applicant: Applied Materials Israel Ltd., Rehovot (IL)

(72) Inventors: Denys Mets, Petah Tiqwa (IL); Pavel Komissarov, Nes-Ziona (IL)

(73) Assignee: Applied Materials Israel Ltd., Rehovot (IL)

(21) Appl. No.: 19/440,440

(22) Filed: Jan. 5, 2026

(30) Foreign Application Priority Data
Jan. 8, 2025 (IL) 318245

(51) Int. Cl. H03F 3/21; H03F 1/26

(52) U.S. Cl. CPC H03F 3/21; H03F 1/26; H03F 2200/15; H03F 2203/21127

(57) ABSTRACT

A voltage modulator for modifying the magnitude of an input signal is provided. The voltage modulator comprises an upstream main input for receiving the input signal, a downstream main output configured to deliver the modified output signal, and an operative block comprising a plurality of gain blocks spanning between the main input and output. Each of the gain blocks comprises a transistor comprising a source, a drain, and a gate, the transistor being configured to vary conductivity between the source and the drain based on a voltage applied to the gate; a block output; and a biasing block connected to the drain of the transistor via the block output and to the gate of the transistor, and configured to facilitate maintaining the transistor in its saturation region. The transistor source of each gain block is connected to the block output of an adjacent upstream gain block.

### CROSS-REFERENCES TO RELATED APPLICATIONS

This application claims priority to Israel Patent Application No. 318245, filed Jan. 8, 2025, the contents of which are incorporated herein by reference in their entirety for all purposes.

### TECHNOLOGICAL FIELD

The presently disclosed subject matter relates to high-voltage power supplies, and in particular to voltage modulators suitable therefor.

### BACKGROUND OF THE INVENTION

Many industrial applications require a high voltage, for example greater than 1 kV, and sometimes exceeding tens or even hundreds of kV. For applications in which power is required at intervals, such as an electrostatic chuck in the semiconductor industry in which a voltage is applied to a workpiece to hold it in place (biasing) and released by removing the voltage (unbiasing), throughput may be limited by the slew rate of the power supply. While increasing the slew rate may lead to higher throughput, it often results in undesirable conditions, such as arcing, partial discharges, etc.

### BRIEF SUMMARY OF THE INVENTION

According to an aspect of the presently disclosed subject matter, there is provided a voltage modulator configured to modify the magnitude of an input signal, the voltage modulator comprising an upstream main-input port for receiving the input signal, a downstream main-output port configured to deliver the modified output signal, and an operative block comprising a plurality of gain blocks spanning between the input and output ports, each of the gain blocks comprising:
a transistor comprising a source, a drain, and a gate, the transistor being configured to vary conductivity between the source and the drain based on a voltage applied to the gate;
a block-output port; and
a biasing block connected to the drain of the transistor via the block-output port and to the gate of the transistor, the biasing block being configured to facilitate maintaining the transistor in its saturation region;
   each of the gain blocks being connected to an upstream gain block adjacent thereto such that the source of its transistor is connected to the block-output port of the upstream gain block.

The biasing block may comprise an upstream bias-input port, a downstream bias-input port, and a bias-output port connected to the gate of the transistor, wherein:
the downstream bias-input port is connected to the block-output port; and
each of the gain blocks is further connected to the upstream gain block adjacent thereto such that the upstream bias-input port of the gain block is connected to the source of the transistor of the upstream gain block.

The biasing block may comprise a voltage divider comprising:
an upstream input-voltage port constituting the upstream bias-input port;
a downstream input-voltage port constituting the downstream bias-input port; and
an output-voltage port constituting the bias-output port;
   the voltage divider being configured to produce an output voltage at the output-voltage port which is smaller than a voltage difference between the voltages applied at the upstream and downstream input-voltage ports.

The voltage divider comprises a resistor-capacitor (RC) circuit between its output-voltage port and at least one of its input-voltage ports.

The RC circuit may be a parallel RC circuit comprising a resistor and a capacitor connected in parallel between the output-voltage port and the respective input-voltage port.

The upstream bias-input port of the upstream-most gain block may comprise first and second terminals, the voltage modulator further comprising:
an input block configured to be connected at an upstream side thereof to the main-input port and to be connected at a downstream side thereof to the upstream bias-input port of the upstream-most gain block, the input block comprising:
a direct branch configured to facilitate connecting the main-input port directly to the first terminal; and
a regulating branch configured to facilitate regulating voltage between the main-input port and the second terminal.

The regulating branch may comprise a first regulating transistor comprising:
a source connected to the main-input port via a regulation block;
a drain connected to the second terminal and to the source of the transistor of the upstream-most gain block; and
a gate connected to the main-input port.

The regulation block may comprise a control circuit configured to regulate current therethrough.

The control circuit may comprise an optocoupler, one or more resistors, one or more transistors, and/or an operational amplifier, e.g., wherein there is no need to isolation of the control signal is not required.

The regulating branch may comprise a second regulating transistor configured to regulate flow between the first regulating transistor and the transistor of the upstream-most gain block, the second regulating transistor comprising:
a source connected to the drain of the first regulating transistor;
a drain connected to the source of the transistor of the upstream-most gain block; and
a gate connected to the main-input port.

At least some of the transistors may be n-channel transistors.

At least some of the transistors may be field-effect transistors.

At least some of the transistors may be metal-oxide-semiconductor field-effect transistors and/or high-electron-mobility transistors.

At least some of the transistors may be enhancement-mode type transistors and/or depletion-mode type transistors.

The block-output port of the downstream-most gain block may be connected to the main-output port.

According to another aspect of the presently disclosed subject matter, there is provided a power supply system comprising:
first and second voltage modulators each as described above;
an input port connected to the main-input port of the first voltage modulator;
an output port connected to the main-output port of the second voltage modulator and to the main-input port of the second voltage modulator; and
a ground port configured to be connected to ground.

The second voltage modulator may be connected to ground in parallel with a regulating circuit.

The regulating circuit may comprise a variable resistor.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIGS. 1A through 1D are schematic diagrams of power supply systems according to the presently disclosed subject matter;

FIG. 2 is a schematic diagram of a voltage modulator of the power supply system illustrated in FIG. 1;

FIG. 3 is a representative circuit diagram of a gain block of the voltage modulator illustrated in FIG. 2; and

FIG. 4 is a representative circuit diagram of an input block of the voltage modulator illustrated in FIG. 2.

### DETAILED DESCRIPTION OF THE INVENTION

The presently disclosed subject matter is generally directed towards power supply systems, in particular high-voltage power supply systems such as high-voltage amplifiers. Typically, although not required, the power supply system comprises a source branch and a grounding branch, which is normally closed to ground. These branches according to the presently disclosed subject matter function as voltage modulators, and as such as configured to accept an input signal (such as the input voltage provided to the source branch) and to modify its magnitude to produce an output signal having lower voltage.

The voltage modulators comprise a plurality of gain blocks in a daisy-chain configuration. Each of the gain blocks is configured to partially modify the magnitude of the input signal. This facilitates providing robust high-voltage power supply systems which, e.g., exhibit reduced settling time and/or low residual voltage compared to conventional power supply systems. In addition, this may further reduce the probability of adverse conditions such as arcing, flashovers, and partial discharge.

It will be appreciated that the preceding is provided as an introductory overview to provide a general synopsis of the presently disclosed subject matter. Accordingly, it is not to be construed as limiting. Similarly, the inclusion of specific details therein, exclusion of specific details therefrom, generalizations, particularizations, etc., are not to be construed as limiting.

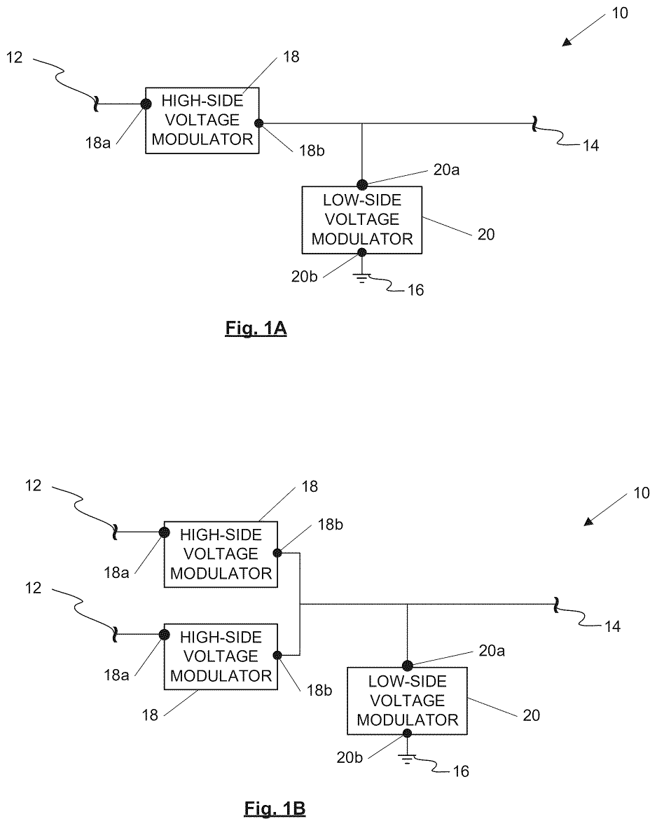

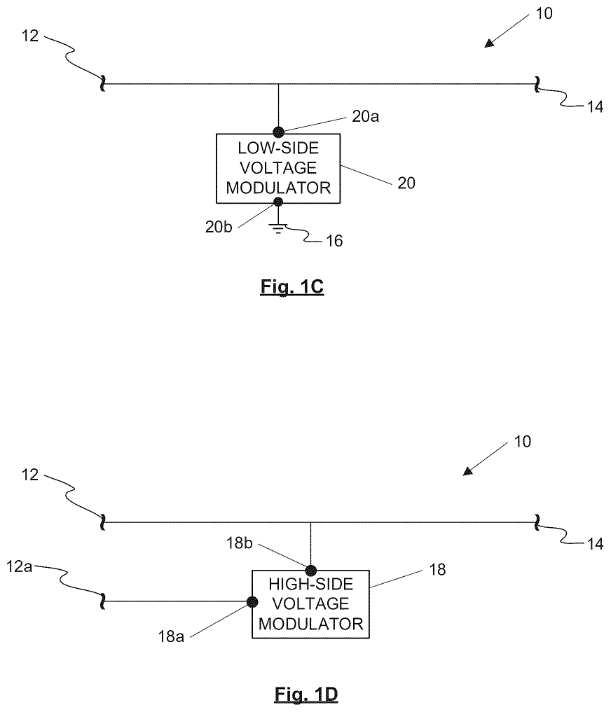

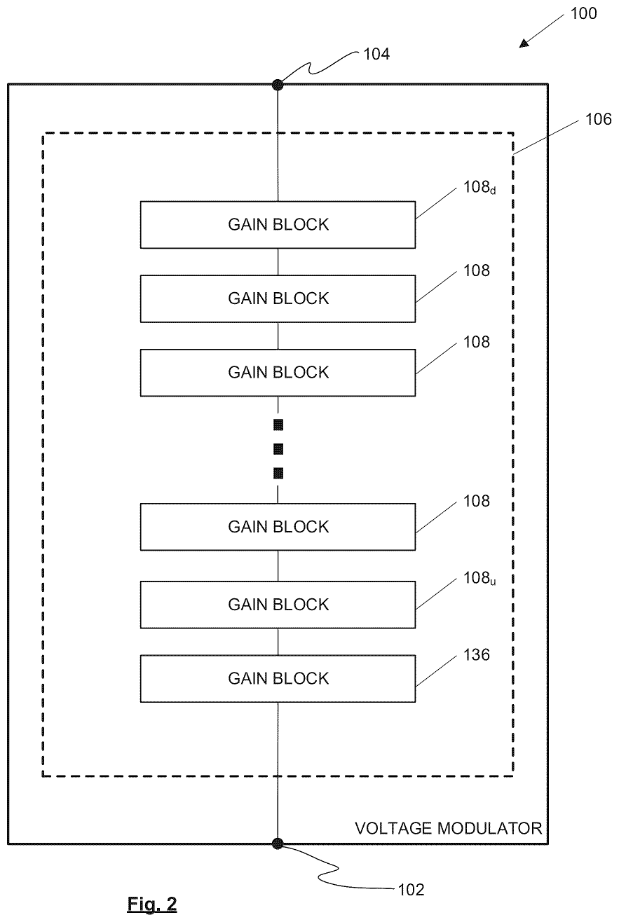

As illustrated in FIG. 1A, there is provided a power supply system, which is generally indicated at 10. According to some examples, the power supply system 10 is configured to supply electrical power at high voltages, for example above 1 kV.

The power supply system 10 is configured to receive an input voltage at 12, to provide electrical power with a modulated output voltage at 14, and to be grounded at 16. It comprises a high-side voltage modulator 18 connected to the input voltage 12 via an input port 18a thereof, and a low-side voltage modulator 20 connected to ground 16 via an output port 20 b thereof. An output port 18b of the high-side voltage modulator 18 and an input port 20a of the low-side voltage modulator 20 are connected to each other and to the output voltage 14 via a mutual connection.

The high-side voltage modulator 18 may constitute a current source branch of the power supply system 10. The low-side voltage modulator 20 may be normally closed to ground. According to some examples, the power supply system 10 may comprise one or more feedback circuits, one or more protection circuits, etc. (not shown), connected to high-side voltage modulator 18 and/or the low-side voltage modulator 20, for example as is known in the art. The power supply system 10 may be configured such that when the low-side voltage modulator 20 is closed, i.e., it operates to allow current to pass therethrough, thereby grounding the system.

According to some examples, for example as illustrated in FIG. 1B, the power supply system 10 may constitute a bipolar power supply. According to these examples, the power supply system 10 is configured to receive two input voltages at 12, to provide electrical power with a modulated voltage at 14, and to be grounded at 16. It comprises two high-side voltage modulators 18, each connected to one of the input voltages 12 via an input port 18a thereof, and a low-side voltage modulator 20 connected to ground 16 via an output port 20 b thereof. The high-side and low-side voltage modulators 18, 20 are connected to each other and to the output voltage 14 via a mutual connection. Output ports 18b of the high-side voltage modulator 18 and an input port 20a of the low-side voltage modulator 20 are connected to each other and to the output voltage 14 via a mutual connection.

According to some examples, for example as illustrated in FIG. 1C, the power supply system 10 is configured to receive an input voltage at 12, to provide an output voltage at 14, and to be grounded at 16. The power supply system 10 comprises a low-side voltage modulator 20 connected to the input voltage 12 via an input port 20 a thereof, and to ground 16 via an output port 20b thereof, thereby constituting a sink.

According to some examples, for example as illustrated in FIG. 1D, the power supply system 10 is configured to receive a main input voltage at 12 and a regulating input voltage at 12a, and to provide an output voltage 14. It comprises a high-side voltage modulator 18 connected to the regulating input voltage 12a via an input port 18a thereof, and to the main input voltage 12 via an output port 18b thereof. When the regulating input voltage 12a is negative with reference to the main input voltage 12, the high-side modulator 18 constitutes a sink circuit. When the regulating input voltage 12a is positive with reference to the main input voltage 12, the high-side modulator 18 constitutes a source circuit.

It will be appreciated that the terms “high-side modulator” and “low-side modulator” are used herein for convenience only, and are not to be considered limiting, e.g., it includes examples in which the high-side modulator 18 as described above with reference to FIG. 1D may be better described as a low-side modulator.

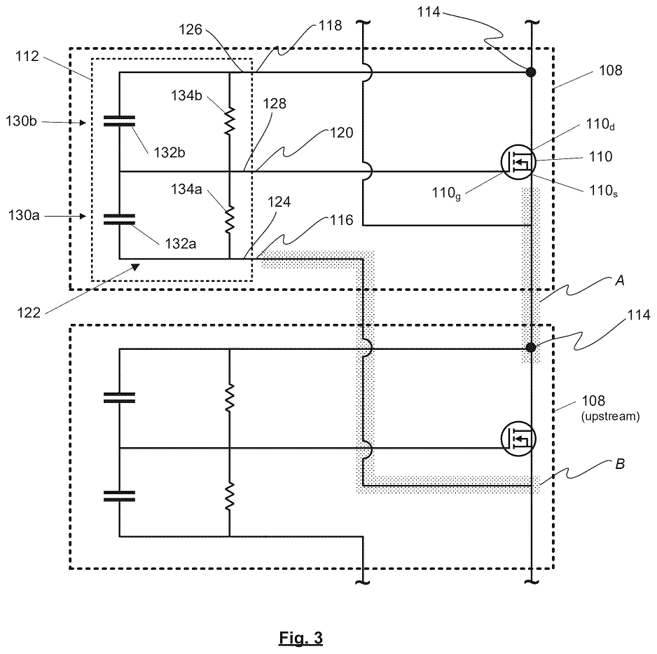

As illustrated in FIG. 2, there is provided a voltage modulator, which is generally indicated at 100, configured to modify the magnitude of an input signal, e.g., the voltage of an input current, for example wherein the current has a high voltage. Each of the high-side and low-side voltage modulators 18, 20 may be provided in accordance with the voltage modulator 100 described herein with reference to and as illustrated in FIG. 2. It will be appreciated, however, that while the high-side and low-side voltage modulators 18, 20 may be provided according to a common overall design, the particulars of each may differ from the other, for example regarding the specifications of elements thereof, provision and/or arrangements of optional features, the quantity of elements which are repeated, etc. Moreover, it will be appreciated that a voltage modulator as described herein with reference to and as illustrated in FIG. 2 may be provided by itself, i.e., not as a component of a power supply system for example as described herein with reference to and as illustrated in FIG. 1.

The voltage modulator 100 comprises a main-input port 102 at an upstream end thereof configured for receiving an input signal, and a main-output port 104 at downstream end thereof configured for delivering an output signal, and an operative block 106 spanning therebetween. The operative block 106 comprises a plurality of gain blocks 108 connected linearly to one another, i.e., connected in a daisy-chain topology, wherein each gain block, besides an upstream-most gain block 108ᵤ and a downstream-most gain block 108_{d}, is connected to one gain block upstream thereof and one gain block downstream thereof.

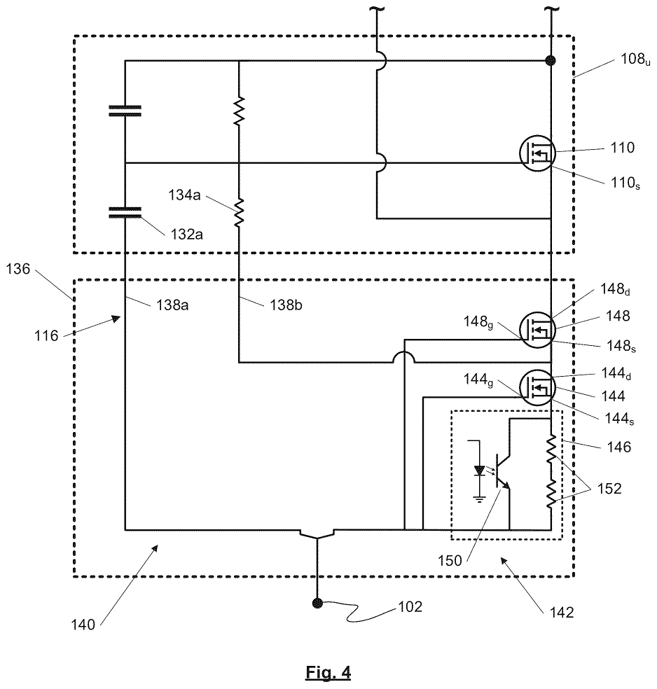

Each of the gain blocks 108 is configured to partially modify the magnitude of the input signal. Accordingly, as illustrated in FIG. 3, each of the gain blocks 108 comprises a transistor 110 and a biasing block 112.

The transistor 110 comprises a source 110ₛ, a drain 110ₛ, and a gate 110_{g}, and is configured to vary the conductivity between the source and the drain based on a voltage applied to the gate, e.g., based on the voltage difference between the source and the gate. The transistor 110 may be any suitable device for example as is known in the art. According to some examples, the transistor 110 may comprise an n-channel transistor. According to some examples, the transistor 110 may comprise a field-effect transistor, for example a metal-oxide-semiconductor field-effect transistor (MOSFET). The transistors 110 may be an enhancement-mode type transistor.

The biasing block 112 may be any suitable element or functional block configured to facilitate maintaining the transistor 110 in its saturation region, thereby facilitating the transistor to provide linear amplification.

The gain block 108 may comprise a block-output port 114 defined at a connection between the drain 110_{d} of the transistor 110 and the biasing block 112. Adjacent gain blocks 108 are connected to one another, inter alia, such that the source 110ₛ of the transistor 110 is connected to the block-output port 114 of the gain blocks upstream thereof, for example as illustrated at A. The block-output port 114 of the downstream-most gain block 108_{d} is connected to the main-output port 104 of the voltage modulator 100, for example as illustrated in FIG. 2.

According to some examples, the biasing block 112 may comprise an upstream bias-input port 116, a downstream bias-input port 118, and a bias-output port 120. The block-output port 114 may be connected to the downstream bias-input port 118, i.e., one of the input ports of the biasing block and the drain 110_{d} of the transistor 110 may be connected to each other. The bias-output port 120 may be connected to the gate 110_{g} of the transistor 110. Adjacent gain blocks 108 may be connected such that the upstream bias-input port 116 of a downstream one of the gain blocks is connected to the source 110ₛ of the transistor 110 of the upstream one of the gain blocks, for example as indicated at B.

The biasing block 112 may comprise a voltage divider 122, configured to produce an output voltage at an output-voltage port thereof which is smaller than a voltage difference between two input voltages applied at input-voltage ports thereof. Accordingly, it may comprise an upstream input-voltage port 124 which constitutes the upstream bias-input port 116, a downstream input-voltage port 126 which constitutes the downstream bias-input port 118, and an output-voltage port 128 constituting the bias-output port 120. It will be appreciated that herein the description and appended claims, recitation of a port of the voltage divider 122 constituting a port of the biasing block 112 is not to be construed as excluding cases in which a circuit element is provided between the port of the voltage divider and that of the biasing block 112; e.g., such an element may be considered to be part of the voltage divider.

The voltage divider 122 may be of any suitable design. According to some examples, it comprises a first resistor-capacitor (RC) circuit 130a between the upstream input-voltage port 124 and the output-voltage port 128, and a second RC circuit 130b between the downstream input-voltage port 126 and the output-voltage port 128. (In the present disclosure, different elements indicated by a single reference numeral and distinguished by their trailing letters may be collectively indicated using the single reference numeral without a trailing letter, e.g., reference numeral 130 may be used to collectively refer to first and second RC circuits 130a, 130b.)

One or both of the RC circuits 130 may be a parallel RC circuit. Accordingly, the first RC circuit 130a may comprise a capacitor 132a and a resistor 134a connected in parallel between the upstream input-voltage port 124 and the output-voltage port 128, and/or the second RC circuit 130b may comprise a capacitor 132b and a resistor 134b connected in parallel between the downstream input-voltage port 126 and the output-voltage port 128.

Reverting to FIG. 2, the operative block 106 may further comprise an input block 136, for example to control current supplied thereto voltage. The input block 136 is connected at an upstream side thereof to the main-input port 102 of the voltage modulator 100, and at a downstream side thereof to the upstream-most gain block 108ᵤ, e.g., to the upstream bias-input port 116 thereof.

According to some examples, for example as illustrated in FIG. 4, the upstream bias-input port 116 of the biasing block 112 of the upstream-most gain block 108ᵤ comprises first and second terminals 138a, 138b. The input block 136 may comprise a direct branch 140 configured to connect the main-input port 102 of the voltage modulator 100 to the first terminal 138a, and a regulating branch 142 configured to connect the main-input port 102 to the second terminal 138b. The regulating 142 branch may be configured to facilitate regulating voltage between the main-input port 102 of the voltage modulator 100 and the second terminal 138b.

According to examples in which the biasing block 112 comprises a voltage divider 122 comprising RC circuits 130, the first terminal 138a of the upstream bias-input port 116 of the biasing block 112 of the upstream-most gain block 108ᵤ may be connected to the capacitor 132a of the first RC circuit 130a, and the second terminal 138b may be connected to the resistor 132b of the second RC circuit 130a.

The regulating branch 142 may comprise first regulating transistor 144 having a source 144ₛ connected to the main-input port 102 of the voltage modulator 100 via a regulation block 146, a drain 144ₛ connected to the second terminal 138b and to the source 110ₛ of the transistor 110 of the upstream-most gain block 108ᵤ, and a gate 144_{g} connected, e.g., directly, to the main-input port of the voltage modulator.

The regulating branch 142 may further comprise a second regulating transistor 148 configured to regulate flow between the first regulating transistor 144 and the transistor 110 of the upstream-most gain block 108ᵤ. Accordingly, the second regulating transistor 148 may comprise a source 148ₛ connected to the drain 144_{d} of the first regulating transistor 144, a drain 148ₛ connected to the source 110ₛ of the transistor 110 of the upstream-most gain block 108ᵤ, and a gate 148_{g} connected, e.g., directly, to the main-input port 102 of the voltage modulator 100.

The regulation block 146 is configured to regulate, e.g., selectively, current passing therethrough. According to some examples, the regulation block 146 may comprise an optocoupler 150, facilitating selectively controlling current flow from the main-input port 102 of the voltage modulator 100 through the operative block 106. According to other examples, the regulation block 146 may comprise one or more regulating resistors 152. According to some examples, the regulation block 146 comprises an optocoupler 150 as described above and one or more regulating resistors 152, for example arranged in parallel as illustrated.

As the magnitude of the input signal operative block 106 comprises a plurality of gain blocks 108, each of the gain blocks may be configured to handle a low voltage, e.g., comprising components which are rated for low voltage. Moreover, this design facilitates scaling, e.g., it may be adapted for use with higher voltages by adding more gain blocks 108. The power supply system 10 in which the high-side voltage modulator 18 and/or low-side voltage modulator 20 are provided as per described above with reference to and as illustrated in FIG. 2 may be designed such that a floating ground is not required. It may also exhibit an increased slew rate, e.g., above 1 kv/sec, reduced noise, reduced partial discharge, shorter settling time, reduced residual voltage, etc., when compared to a comparable high-voltage power supply of conventional design.

It will be appreciated that while the high-side and low-side voltage modulators 18, 20 were both described herein with reference to the voltage modulator 100, this was by way of schematic example only. Accordingly, each may be designed in accordance with the description of the voltage modulator 100 but with different parameters, including, but not limited to, the number of gain blocks 108, the presence of optional and non-disclosed features, the specifications of the elements thereof, etc. Moreover, the power supply 10 may comprise one of the voltage modulators 18, 20 provided according to the voltage modulator 100 as described above, and one having a design not in accordance therewith. Moreover, the voltage modulator 100 may be provided as a standalone component and/or as part of a system other than a power supply system, without departing from the scope of the presently disclosed subject matter, mutatis mutandis.

Herein the specification and appended claims, the terms “upstream,” “downstream,” etc., indicate typical usage, wherein the upstream direction is closer to the input, and the downstream direction is closer to the output. The use of these terms is for clarity and by way of example only, and is not to be construed as limiting.

Herein the specification and appended claims, use of the terms “connected,” “connection,” etc., indicates electrical connection. Typically, it is used to indicate direct electrical connections, for example constituting an electrical node. However, this should not be construed as excluding providing components, circuits, blocks, etc. —which enhance or do not affect overall function—as part of a connection. Examples of such components, circuits, blocks, etc., may be those which are provided for safety, measurement, robustness, etc.

It will be appreciated that while the present description and appended claims relate to circuits comprising individual circuit elements (transistor, resistors, capacitors, etc.), this should not be construed as being limiting. In practice, a functional block may be provided in place of a disclosed circuit element, wherein the functional block comprises a plurality of circuit elements cooperating to perform the function of a disclosed circuit element, without departing from the scope of the presently disclosed subject matter, mutatis mutandis.

It will be recognized that examples, embodiments, modifications, options, etc., described herein are to be construed as inclusive and non-limiting, i.e., two or more examples, etc., described separately herein are not to be construed as being mutually exclusive of one another or in any other way limiting, unless such is explicitly stated and/or is otherwise clear. Those skilled in the art to which this invention pertains will readily appreciate that numerous changes, variations, and modifications can be made without departing from the scope of the presently disclosed subject matter, mutatis mutandis.

What is claimed is:

1. A voltage modulator configured to modify the magnitude of an input signal, the voltage modulator comprising an upstream main-input port for receiving the input signal, a downstream main-output port configured to deliver the modified output signal, and an operative block comprising a plurality of gain blocks spanning between the input and output ports, each of the gain blocks comprising:
a transistor comprising a source, a drain, and a gate, the transistor being configured to vary conductivity between the source and the drain based on a voltage applied to the gate;
a block-output port; and
a biasing block connected to the drain of the transistor via the block-output port and to the gate of the transistor, the biasing block being configured to facilitate maintaining the transistor in its saturation region;
wherein each of the gain blocks is connected to an upstream gain block adjacent thereto such that the source of its transistor is connected to the block-output port of the upstream gain block.

2. The voltage modulator according to claim 1, the biasing block comprising an upstream bias-input port, a downstream bias-input port, and a bias-output port connected to the gate of the transistor, wherein:
the downstream bias-input port is connected to the block-output port; and
each of the gain blocks is further connected to the upstream gain block adjacent thereto such that the upstream bias-input port of the gain block is connected to the source of the transistor of the upstream gain block.

3. The voltage modulator according to claim 2, wherein the biasing block comprises a voltage divider comprising:
an upstream input-voltage port constituting the upstream bias-input port;
a downstream input-voltage port constituting the downstream bias-input port; and
an output-voltage port constituting the bias-output port;
wherein the voltage divider is configured to produce an output voltage at the output-voltage port which is smaller than a voltage difference between the voltages applied at the upstream and downstream input-voltage ports.

4. The voltage modulator according to claim 3, wherein the voltage divider comprises a resistor-capacitor (RC) circuit between its output-voltage port and at least one of its input-voltage ports.

5. The voltage modulator according to claim 4, wherein the RC circuit is a parallel RC circuit comprising a resistor and a capacitor connected in parallel between the output-voltage port and the respective input-voltage port.

6. The voltage modulator according to claim 2, the upstream bias-input port of the upstream-most gain block comprising first and second terminals, the voltage modulator further comprising:
an input block configured to be connected at an upstream side thereof to the main-input port and to be connected at a downstream side thereof to the upstream bias-input port of the upstream-most gain block, the input block comprising:
a direct branch configured to facilitate connecting the main-input port directly to the first terminal; and
a regulating branch configured to facilitate regulating voltage between the main-input port and the second terminal.

7. The voltage modulator according to claim 6, wherein the regulating branch comprises a first regulating transistor comprising:
a source connected to the main-input port via a regulation block;
a drain connected to the second terminal and to the source of the transistor of the upstream-most gain block; and
a gate connected to the main-input port.

8. The voltage modulator according to claim 7, wherein the regulation block comprises a control circuit configured to regulate current therethrough.

9. The voltage modulator according to claim 8, wherein the control circuit comprises an optocoupler.

10. The voltage modulator according to claim 7, wherein the voltage modulator comprises one or more resistors.

11. The voltage modulator according to claim 7, wherein the regulating branch comprises a second regulating transistor configured to regulate flow between the first regulating transistor and the transistor of the upstream-most gain block, the second regulating transistor comprising:
a source connected to the drain of the first regulating transistor;
a drain connected to the source of the transistor of the upstream-most gain block; and
a gate connected to the main-input port.

12. The voltage modulator according to claim 1, wherein at least some of the transistors are n channel transistors.

13. The voltage modulator according to claim 1, wherein at least some of the transistors are field-effect transistors.

14. The voltage modulator according to claim 13, wherein at least some of the transistors are high-electron-mobility transistors.

15. The voltage modulator according to claim 13, wherein at least some of the transistors are enhancement-mode type transistors.

16. The voltage modulator according to claim 13, wherein at least some of the transistors are depletion-mode type transistors.

17. The voltage modulator according to claim 1, wherein the block-output port of the downstream-most gain block is connected to the main-output port.

18. A power supply system comprising:
first and second voltage modulators each according to claim 1;
an input port connected to the main-input port of the first voltage modulator;
an output port connected to the main-output port of the second voltage modulator and to the main-input port of the second voltage modulator; and
a ground port configured to be connected to ground.

19. The power supply system according to claim 18, wherein the second voltage modulator is connected to ground in parallel with a regulating circuit.

20. The power supply according to claim 19, wherein the regulating circuit comprises a variable resistor.
